(19) United States
(12) Patent Application Publication
(10) Pub. No.: US 2022/0415755 A1
(43) Pub. Date: Dec. 29, 2022

(54) Method for Producing a Cooling Element

(71) Applicant: Siemens Aktiengesellschaft, München (DE)

(72) Inventor: Olaf Rehme, Hamburg (DE)

(73) Assignee: Siemens Aktiengesellschaft, München (DE)

(21) Appl. No.: 17/620,818

(22) PCT Filed: May 22, 2020
(86) PCT No.: PCT/EP2020/064316

§ 371 Date: Dec. 20, 2021

(30) Foreign Application Priority Data
Jun. 19, 2019 (EP) 19181328.6

(51) Int. Cl. H01L 23/473; B23P 15/26; H01L 21/48

(52) U.S. Cl. CPC H01L 23/473; B23P 15/26; H01L 21/4871

(57) ABSTRACT

Various embodiments of the teachings herein include a process for producing a cooling element. The method may include: providing a main element composed of a first material and having one or more cooling channels; applying a first layer of a second material to a surface of the one or more cooling channels; introducing a filler serving as support material for a second layer; applying the second layer of the second material, so that one or more closed channels made up of the first layer and the second layer are formed in the one or more cooling channels; and applying a covering layer to the one or more closed channels.

### CROSS-REFERENCE TO RELATED APPLICATIONS

This application is a U.S. National Stage Application of International Application No. PCT/EP2020/064316 filed May 22, 2020, which designates the United States of America, and claims priority to EP Application No. 19181328.6 filed Jun. 19, 2019, the contents of which are hereby incorporated by reference in their entirety.

### TECHNICAL FIELD

The present disclosure relates to cooling elements. Various embodiments include processes for producing a cooling element and/or cooling elements suitable for power semiconductors, in particular for thyristors.

### BACKGROUND

Power semiconductors are components which can be installed in electricity-conducting regions and have to have good electrical conductivity. Typically, a cooling liquid flows through them. Here, use is made, in particular, of deionized cooling water in order to avoid conductivity of the water and thus the risk of a short circuit. From the point of view of thermal and electrical conductivity, it is often attractive to make the cooling element of a material which has good electrical and thermal conductivity, e.g. copper. These materials are often not corrosion-resistant, which is particularly important when corrosive cooling liquids, e.g. deionized water, are used. The cooling element may be used in further power electronics and can also be used, for example, for MOSFETs, IGBTs, diodes and GTOs.

### SUMMARY

It is an object of the invention to provide a process which makes it possible to manufacture a cooling element from a material which has good thermal and electrical conductivity and at the same time to ensure a satisfactory corrosion resistance. For example, some embodiments include a process for producing a cooling element (10), comprising the steps: provision (S1) of a main element (100) composed of a first material (M1) and having one or more cooling channels (110), application (S2) of a first layer (111) of a second material (M2) to a surface (115) of the cooling channels (110), introduction (S3) of a filler (130) so that this filler serves as support material for a second layer (112), application (S4) of the second layer (112) of the second material (M2), so that one or more closed channels (125) made up of the first layer (111) and the second layer (112) are formed in the cooling channels (110), and application (S5) of a covering layer (150) to the closed channels (125).

In some embodiments, the second material (M2) serves as corrosion protection for the first material (M1).

In some embodiments, the first material (M1) is copper or a copper alloy.

In some embodiments, the second material (M2) is aluminum or an aluminum alloy.

In some embodiments, the filler (130) has been or is provided with a bonding layer.

In some embodiments, the method further comprises working (S21) of the first layer (111) so that excess second material (M2) is removed and/or so that the first layer (111) has a defined dimension.

In some embodiments, the method further comprises the step: smoothing (S41) of the second layer (112) so that the second layer (112) is made flush with the main element (100).

In some embodiments, the method further comprises smoothing of the covering layer (150).

In some embodiments, the second material (M2) is applied at least partly by means of a cold gas spray process.

In some embodiments, the cooling channels (110) have, in cross section, a tapering shape, in particular a funnel shape.

As another example, some embodiments include a cooling element (10) comprising a main element (100) composed of a first material and also one or more cooling channels (110), wherein the cooling channels (110) have a closed channel (125) composed of a second material (M2) and the closed channel (125) has a first layer (111) and a second layer (112).

### BRIEF DESCRIPTION OF THE DRAWINGS

In the following, the teachings of the present disclosure will be described in more detail and explained with the aid of the working examples depicted in the figures. The figures show:

FIG. 1 shows a cooling element incorporating teachings of the present disclosure;

FIG. 2 shows a main element incorporating teachings of the present disclosure;

FIG. 3 shows application of a first layer incorporating teachings of the present disclosure;

FIG. 4 shows working of the first layer incorporating teachings of the present disclosure;

FIG. 5 shows a main element with fillers incorporating teachings of the present disclosure;

FIG. 6 shows application of a second layer incorporating teachings of the present disclosure;

FIG. 7 shows a cooling element in a further embodiment incorporating teachings of the present disclosure;

FIG. 8 shows smoothing of the second layer incorporating teachings of the present disclosure; and

FIG. 9 various cross sections of the cooling channels incorporating teachings of the present disclosure.

### DETAILED DESCRIPTION

The present disclosure describes a process for producing a cooling element for power semiconductors, in particular for thyristors. In some embodiments, the process encompasses the steps indicated below.

In some embodiments, the method includes provision of a main element composed of a first material, where the main element has one or more cooling channels. The first material here is a material having a high thermal conductivity or low thermal resistance (in particular copper, but not restricted thereto). The cooling channels can be configured so that they are still open at the top, i.e., do not have to be covered so that a closed cooling system is formed.

In some embodiments, a first layer of a second material (in particular aluminum, but not restricted thereto) is applied to a surface of the cooling channels. The second material may be configured so that it serves as corrosion protection for the first material. The application of the second material is preferably carried out by a cold gas spray process (“cold spray”).

In some embodiments, a filler is introduced into the cooling channels so that this serves as support material for a second layer (112). In other words, the filler composed of a third material is introduced into the cooling channels or applied to the first layer so that the open cooling channels are filled. The third material serving as filler may be of such a nature that it can easily be removed again later. The third material may be, in particular, a polymer, but is not restricted thereto. The application of the third material may be carried out in molten form or by a 3D printing process. The filler can thus be introduced into the cooling channels in order to apply the second layer. For a closed channel made up of a first layer and second layer to be able to be formed, the filler is arranged within the first layer. The filler here serves to support the second layer, and the second layer is subsequently applied to the filler.

In some embodiments, the filler is arranged in the cooling channels or is to be applied to the first layer in such a way that a closed channel made up of a first layer and second layer can be formed. The filler can preferably be a water-soluble filler. However, it is likewise possible to use fillers which are soluble in other solvents, e.g., polymers. These can be applied or introduced in molten form. In some embodiments, the filler is removed before first use of the cooling element. It is not absolutely necessary for the filler to be a soluble filler; the filler can also be a filler which can be flushed out by means of a liquid or a gas or be burnt out or reliquefied and flushed out by means of heat treatment.

In some embodiments, a second layer of the second material is applied in such a way that one or more closed channels made up of the first layer and the second layer are formed in the cooling channels. The application of the second layer may be carried out using a cold gas spray process.

In some embodiments, a covering layer is applied to the closed channels. The covering layer can once again consist of the first material and have particularly good thermal conductivity properties. The covering layer can be composed of a material which is not corrosion resistant since the second material forms intrinsically closed channels and thus protects the main element and the covering layer. This forms a cooling element which has the positive properties of the first material in respect of thermal conduction and the positive properties of the second material in respect of corrosion.

In some embodiments, the covering layer is a layer which can be made up of a material which has particularly good thermal conductivity, for example the first material, i.e., for example, copper. The covering layer can be applied using additive manufacturing methods such as a cold spray process. The main element can, for example, be produced by means of a milling machine from a solid body or be provided using other processes, e.g., casting or forming processes.

In some embodiments, the second material serves as corrosion protection for the first material. This can, for example, be effected by using aluminum as second material, which forms a passivation layer on contact with oxygen.

In some embodiments, the filler has been or is provided with a bonding layer. This improves the adhesion and formation of the second layer. The bonding layer is, in particular, provided on the surface of the filler.

In some embodiments, the first material is copper or a copper alloy. Furthermore, the second material can be aluminum or an aluminum alloy. A combination of the two materials a virtually ideal thermal conductivity as a result of the copper and a very good corrosion resistance as a result of the aluminum, so that it is possible to use highly corrosive coolants such as deionized water.

In some embodiments, the process encompasses working of the first layer so that excess second material is removed. In some embodiments, the first layer can also be worked to a defined dimension. This can occur by working using a milling machine so that the first layer has a defined thickness in the cooling channel. Further treatment steps can be smoothing, equalization and a surface treatment, so that the second layer adheres better.

In some embodiments, the process involves a step of smoothing of the second layer. Smoothing serves primarily to make the second layer flush with the main element, so that, for example, a covering layer can be applied flush. The smoothing of the second layer can naturally be carried out only when the second layer has already been applied. It is possible for the second layer to be covered directly with a covering layer without further aftertreatment.

In some embodiments, the covering layer is smoothed. This can be carried out by appropriate cutting machining, for example milling, or by grinding processes.

In some embodiments, the second material is at least partly applied by means of a cold gas spray process. The steps of application can thus be carried out completely, partly and/or in sections by means of a cold gas spray process (“cold spray” process). The first layer and the second layer can thus be applied using a cold spray process, and the covering layer can likewise be applied by means of a cold spray process. Application, in particular of the first and second layers, by means of a cold spray process may provide surface quality and corrosion resistance particularly high with low process costs.

In some embodiments, the cooling channels have a tapering cross section. The tapering shape can extend only over parts of the cooling channels. In particular, a funnel shape may be advantageous. A taper from the opening of the cooling channel in the direction of the bottom of the cooling channel allows the side faces and the bottom of the cooling channels to be particularly readily reached for coating with the second material.

In some embodiments, there may be a cooling element which comprises a main element composed of a first material. The main element here has one or more cooling channels. Furthermore, the cooling channels each comprise at least one closed channel composed of a second material. The closed channel has a first layer and a second layer.

Some embodiments include a cooling element which has been produced by the process according to any of the above described methods.

FIG. 1 shows a cooling element 10 for a power semiconductor, in particular for thyristors. The cooling element 10 comprises a main element 100 composed of a first material M1 and cooling channels 110. The cooling channels 110 each comprise closed channels 125 which isolate the walls of the cooling channels from the interior space of the closed channels 125 and thus protect them against corrosion. For this purpose, the closed channels 125 can consist of a corrosion-resistant material, e.g., aluminum. This makes it possible for the main element to be made of a material which has particularly good thermal conductivity but is not resistant to corrosive cooling liquids. Copper or a copper alloy may be well suited as first material M1. A covering layer 150, which is likewise composed of the first material M1, covers the cooling channels 110, the closed channels 125 thereof and also the main element 100. The covering layer 150 can serve as contact area to a power semiconductor to be cooled. The covering layer 150 and the main element 100 can, depending on the application, also be made of different materials.

FIG. 2 shows a main element 100 composed of a first material M1 in the blank state. The main element has depressions which are configured as cooling channels 110. These are open at the top and are thus simple to produce. The cooling channels 110 each have a surface 115 which has to be protected against corrosion since potentially corrosive cooling liquid flows in the cooling channels 110 during ongoing operation. The provision S1 of the main element 100 can occur by means of finished parts obtained by cutting machining of a solid piece or by further manufacturing methods. It is likewise conceivable to produce a main element 100 by additive manufacture.

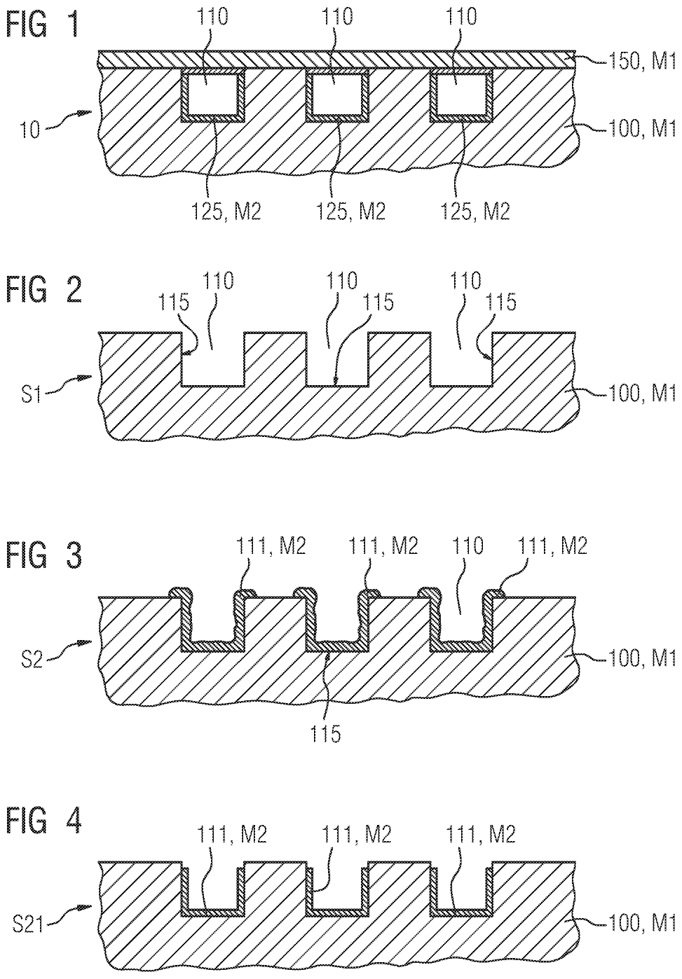

FIG. 3 shows the application S2 of a first layer 111 composed of a second material M2 to the surface 115 of the cooling channels 110. The application S2 is preferably carried out using a cold spray process. The layer formed in this way is particularly inexpensive to produce and has a high corrosion resistance.

FIG. 4 shows a step of working S21 of the first layer 111. The previously uneven surface of the first layer 111, as could be seen in FIG. 3, is brought to a defined dimension and a smooth surface by means of a milling machine. This represents a good starting point for further working or is already the final state for the lower part of the first layer in the cooling channels 110. The working S21 can be dispensed with when the first layer 111 itself already meets the requirements in respect of the nature of the surface of the closed channels 125 by virtue of the application S2. The first layer 111 is thus treated by the working step S21 so that the surfaces have the required dimensions and that the excess materials of the first layer 111 have been removed. The first layer 111 consists of a second material M2 which serves as corrosion protection for the main element 100.

FIG. 5 shows a main element 100 having a worked first layer 111 as is known from FIG. 4. The cooling channels have now been filled with a filler 130 composed of a third material M3 by a step of introduction S3; this filler serves as support material for application of a second layer 112. The third material M3 can, for example, be a water-soluble polymer.

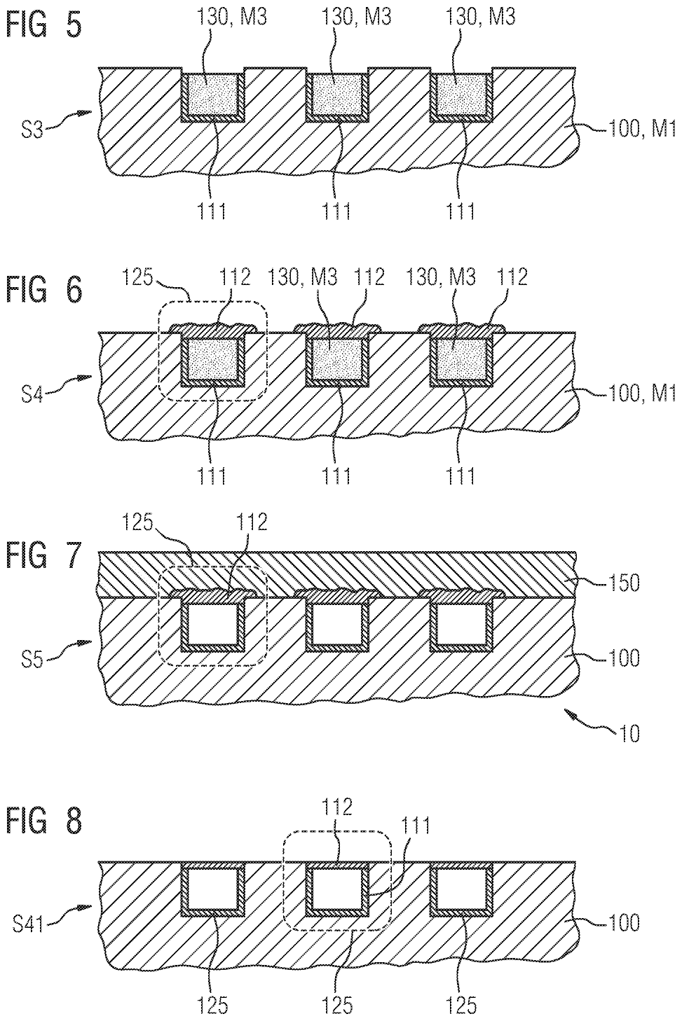

FIG. 6 shows the application S4 of a second layer 112 to the filler 130 and also the first layer 111, so that a closed channel 125 is formed. For this purpose, the filler can be provided beforehand with a bonding layer (not shown) which is based, for example, on silver, aluminum, antimony, magnesium, tin, zinc, lead, tantalum or on a mixture and/or at least one alloy thereof. The bonding layer optionally comprises additionally fillers, for example a ceramic material.

The closed channel 125 protects the main element against corrosion and in this case encloses the filler 130. It is likewise conceivable for the second layer 112 to be applied without filler 130 by means of additive manufacturing methods.

FIG. 7 shows a cooling element 10, wherein a covering layer 150 has been applied to the main element 100 and also to the closed channels 125 or the cooling channels 110 in a step of application S5. The surface of the second layer 112 has in this case been subjected only to minor further working, if any, compared to FIG. 1 for example. The step of smoothing of the covering layer 150 can be carried out with completed application S5 of the covering layer 150, regardless of whether the second layer 112 has been smoothed.

FIG. 8 shows a step of smoothing S41 of the second layer 112. The second layer is thus flush with the main element 100. A covering layer 150 having a high quality can then be applied in order to obtain the cooling element 10 known from FIG. 1. The smoothing S41 can be carried out by known methods, e.g., cutting machining methods. If a particularly high surface quality is required, grinding processes can subsequently be provided.

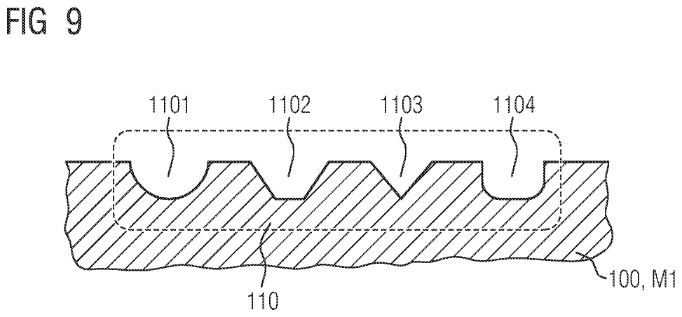

FIG. 9 shows a main element 100 composed of a first material M1 with differently configured cooling channels 110. The cooling channels each have a tapering cross section 1101, 1102, 1103, 1104 and have, from left to right, a round cross section 1101, a funnel-shaped cross section 1102, a cross section 1103 running to a point and a cross section 1104 having rounded edges and a flat bottom.

In summary, the present disclosure describes a process for producing a cooling element 10 and also provides a cooling element 10. In order to manufacture a cooling element 10 from a material M1 which has good thermal and electrical conductivity and at the same time ensure satisfactory corrosion resistance, a method may include the following steps:
provision S1 of a main element 100 composed of a first material M1 and having one or more cooling channels 110,
application S2 of a first layer 111 of a second material M2 to a surface 115 of the cooling channels 110,
introduction S3 of a filler 130 so that the latter serves as support material for a second layer 112,
application S4 of the second layer 112 of the second material M2, so that one or more closed channels 125 made up of the first layer 111 and the second layer 112 are formed in the cooling channels 110 and
application S5 of a covering layer 150 to the closed channels 125.

The steps S1, . . . , S5 can be carried out in the order shown, but it is also possible for individual steps to be combined or to be carried out at a different juncture.

### LIST OF REFERENCE SYMBOLS

10 cooling element
100 main element
110 cooling channels
111 first layer
112 second layer
115 surface
125 closed channels
130 filler
150 covering layer
S1 provision
S2 application of a first layer
S3 introduction of a filler
S4 application of a second layer
S5 application of a covering layer
S21 working of the first layer
S41 smoothing of the second layer
M1 first material
M2 second material
M3 third material

What is claimed is:

1. A process for producing a cooling element, the method comprising
providing a main element composed of a first material and having one or more cooling channels;
applying a first layer of a second material to a surface of the one ore more cooling channels;
introducing a filler serving as support material for a second layer;
applying the second layer of the second material, so that one or more closed channels made up of the first layer and the second layer are formed in the one or more cooling channels; and
applying a covering layer to the one or more closed channels.

2. The process as claimed in claim 1, wherein the second material serves as corrosion protection for the first material.

3. The process as claimed in claim 1, wherein the first material comprises copper.

4. The process as claimed in claim 1, wherein the second material comprises aluminum.

5. The process as claimed in claim 1, wherein the filler includes a bonding layer.

6. The process as claimed in claim 1, further comprising working the first layer so excess second material is removed and/or so that the first layer has a defined dimension.

7. The process as claimed in claim 1, further comprising smoothing the second layer flush with the main element.

8. The process as claimed in claim 1, further comprising smoothing the covering layer.

9. The process as claimed in claim 1, wherein the second material is applied using a cold gas spray process.

10. The process as claimed in claim 1, wherein the cooling channels have, in cross section, a tapering shape.

11. A cooling element comprising:
a main element composed of a first material; and
one or more cooling channels formed in the main element;
wherein the one or more cooling channels have at least one closed channel composed of a second material; and
the at least one closed channel includes a first layer and a second layer.
